(19) United States
(12) Patent Application Publication
(10) Pub. No.: US 2012/0088031 A1
(43) Pub. Date: Apr. 12, 2012

(54) GAS DISCHARGE PIPE AND ASSOCIATED METHOD

(75) Inventor: Thierry NEEL, Meythet (FR)

(73) Assignee: ADIXEN VACUUM PRODUCTS, Annecy (FR)

(21) Appl. No.: 13/267,694

(22) Filed: Oct. 6, 2011

(30) Foreign Application Priority Data
Oct. 8, 2010 (FR) 1003987

(51) Int. Cl. C23C 16/00

(52) U.S. Cl. 427/255.28; 118/715

(57) ABSTRACT

The embodiments of the present invention describe a gas discharge pipe comprising a first discharge channel and at least one second discharge channel designed to be connected respectively to a first vacuum pump and to at least a second vacuum pump on the one hand and to a reactor outlet on the other hand, in which the first discharge channel and at least the second discharge channel comprise first means and at least second means for injecting an inert gas in which the direction of injection is respectively oriented opposite to the direction of suction of the vacuum pumps.

The present invention relates to the discharge of the gases from a reactor and more particularly the discharge of the reactive gas residues leaving a chemical reactor such as the reactor of an item of atomic layer deposition equipment.

The usual operation of an item of atomic layer deposition equipment according to the prior art is described below. Two reactive gases G1 and G2 are inserted sequentially into a reactor in which there is a substrate (“wafer”) in order to allow the deposition of an atomic layer on the wafer. A high temperature is maintained in the reactor by heating elements. The residue of reactive gas (G1 or G2) is discharged through a discharge pipe situated at the outlet of the reactor to a vacuum pump.

The problem with such a method is that the two reactive gases G1 and G2 can get mixed at the vacuum pump. Such a mixture can produce chemical reactions leading to the formation of solid particles and powders in the vacuum pump which is used to discharge the gases G1 and G2. The solid particles and powders accumulating in the vacuum pump can lead to a failure and/or to premature wear of the vacuum pump thereby affecting the overall manufacturing cost of the wafers.

In order to overcome this problem, the solutions of the prior art correspond to using two distinct vacuum pumps, each being dedicated to one reactive gas. The transmission to one or the other of the vacuum pumps being carried out by a system of mechanical valves at the inlet of the discharge pipe directing the reactive gas to one or the other of the discharge channels of the pipe to which the vacuum pumps are connected.

Nevertheless, with such solutions, the mixing of the reactive gases can occur at the mechanical valves, causing the deposition of a layer of sub-product at the valves which can disrupt their operation and lead to a failure.

The object of the invention is therefore to propose a device making it possible to prevent a mixture of the reactive gases in the mechanical elements in motion in order to prevent the formation of sub-products that can lead to an operating failure and also allowing the reactive gas to be directed from one discharge channel to another discharge channel in a manner that is more rapid and therefore more suited to the pulsed methods such as the atomic layer deposition method.

Therefore, the device according to the present invention is a gas discharge pipe comprising a first discharge channel and at least one second discharge channel designed to be connected respectively to a first vacuum pump and to at least a second vacuum pump on the one hand and to a reactor outlet on the other hand, in which the first discharge channel and at least the second discharge channel comprise first means and at least second means for injecting an inert gas whose direction of injection is respectively oriented opposite to the direction of suction of the vacuum pumps.

An “inert gas” is understood to be a single inert gas or a mixture of inert gases. The inert gas may, for example, be nitrogen N₂, argon Ar and/or helium He.

According to another aspect of the present invention, the pipe comprises a central trunk placing in communication on the one hand the outlet of the reactor and on the other hand the first discharge channel and at least the second discharge channel, the first discharge channel and at least the second discharge channel having conductances of the same order of magnitude.

According to an additional aspect of the present invention, the discharge channels are two in number and the central trunk comprises on the one hand an internal portion in communication with the first discharge channel and on the other hand a peripheral portion separated from the internal portion by a wall, being in communication with the second discharge channel.

According to a supplementary aspect of the present invention, the respective conductances of the internal portion and of the peripheral portion of the central trunk are of the same order of magnitude.

According to another aspect of the present invention, the first injection means for injecting an inert gas are situated in the axis of the internal portion of the central trunk and are oriented towards the outlet of the reactor while the second injection means for injecting an inert gas are situated on the perimeter of the peripheral portion of the central trunk, and are oriented substantially towards the centre of the section of the central trunk.

A further subject of the present invention is a method for discharging a first reactive gas and at least one second reactive gas originating from a reactor through a discharge pipe, the first reactive gas and at least the second reactive gas being discharged sequentially through a first discharge channel and at least one second discharge channel connected to a first vacuum pump and at least one second vacuum pump, in which the directing of the flow of a reactive gas towards one of the discharge channels is controlled by the injection of an inert gas substantially in the direction opposite to the direction of suction of the respective vacuum pumps.

According to another aspect of the present invention, the injection of inert gas is carried out at the inlet of at least one of the first and second discharge channels.

According to an additional aspect of the present invention, the first reactive gas and at least second reactive gas originating from the reactor are received sequentially, and the first vacuum pump and at least second vacuum pump are dedicated respectively to the first reactive gas and at least to the second reactive gas so that an inert gas is injected at the first discharge channel when the reactive gas to be discharged is sent to the second vacuum pump and an inert gas is injected at the second discharge channel when the reactive gas to be discharged is sent to the first vacuum pump.

According to a supplementary aspect of the present invention, the first reactive gas and at least the second reactive gas originating from the reactor are received alternately, so that the injection of an inert gas at the discharge channels is also carried out alternately.

According to another aspect of the present invention, the quantity of inert gas that is injected is the same for the two sequences of the alternation and is calculated to obtain a concentration of 20% reactive gas in the gas mix at the vacuum pump, the gas mix at the vacuum pump consisting of reactive gas and injected inert gas.

Other features and advantages of the invention will appear in the description which will now be made, with reference to the appended drawings which represent, as a nonlimiting indication, one possible embodiment thereof.

In these drawings:

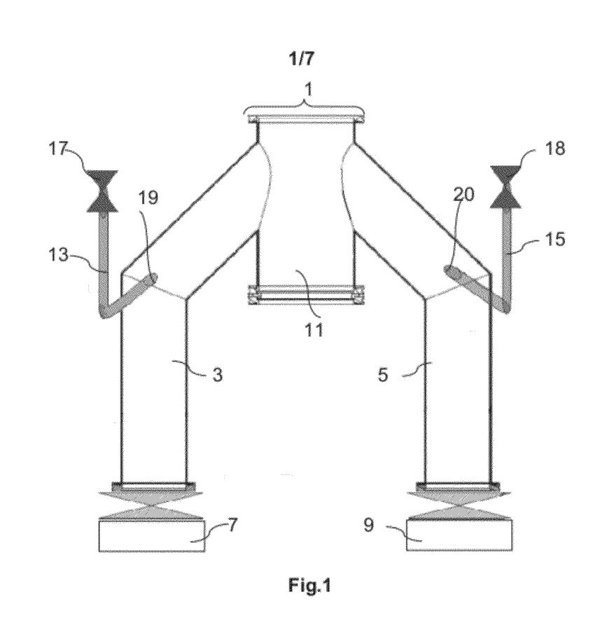

FIG. 1 shows a diagram of a first embodiment of a discharge pipe according to the present invention;

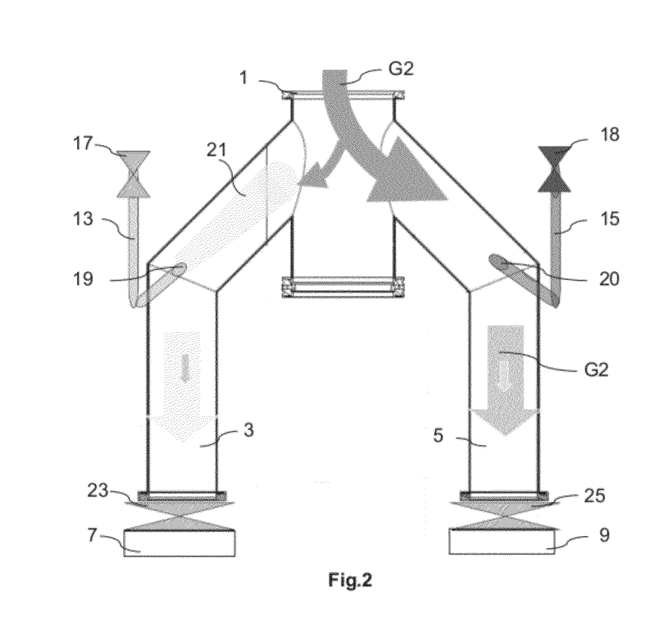

FIG. 2 shows a diagram of the first embodiment of a discharge pipe according to the present invention when the first means for injecting inert gas are activated;

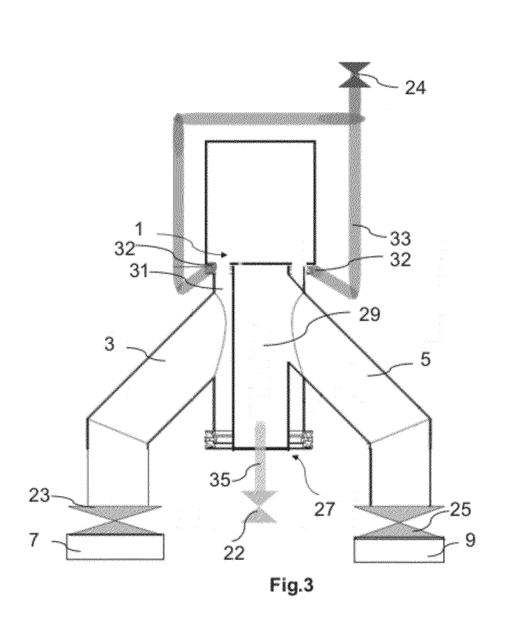

FIG. 3 shows a diagram of a second embodiment of a discharge pipe according to the present invention;

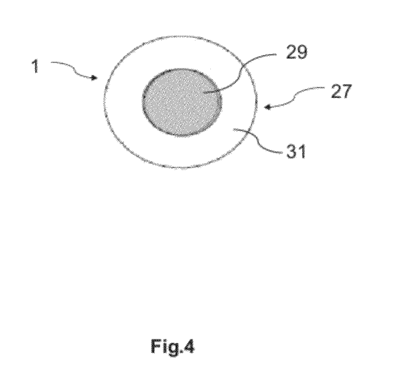

FIG. 4 shows a diagram of a view in cross section of the pipe at the inlet of the pipe for the second embodiment of the present invention;

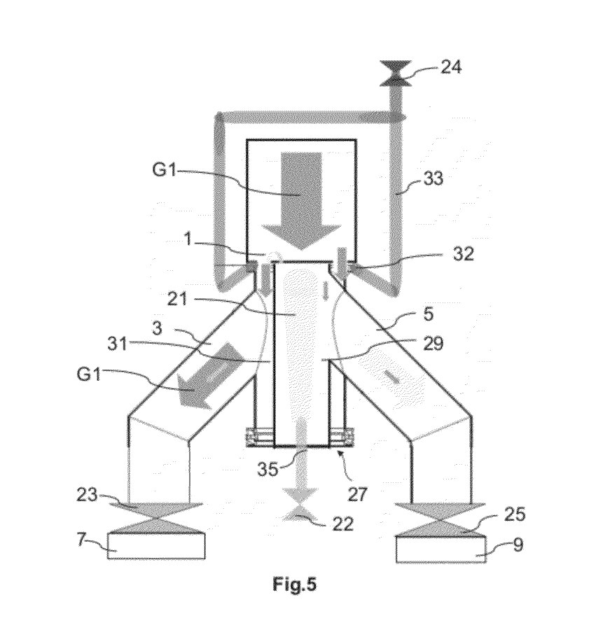

FIG. 5 shows a diagram of a first operating step of the second embodiment of a discharge pipe according to the present invention when the first means for injecting inert gas are activated;

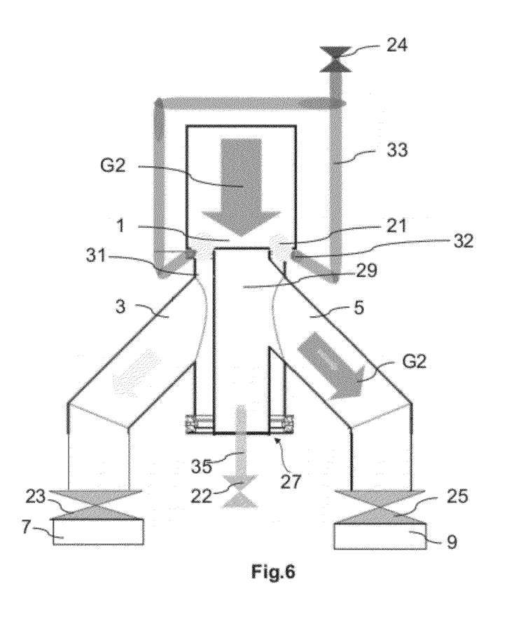

FIG. 6 shows a diagram of a second operating step of the second embodiment of a discharge pipe according to the present invention when the second means for injecting inert gas are activated;

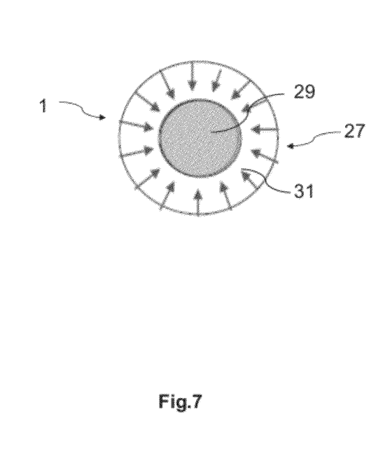

FIG. 7 shows a diagram of a view in cross section of the pipe at the inlet of the pipe and the direction of the inert gas when the second injection means are activated.

In the context of the present invention, the “conductance” of a pipe is the quotient of the flow divided by the pressure difference upstream and downstream of the pipe and corresponds to the ease of flow of a fluid in the pipe.

The embodiments of the present invention relate to the use of an inert gas in a discharge pipe for reactive gas originating from a reactor, for example an atomic layer deposition reactor, comprising at least two discharge channels in order to direct the reactive gas to be discharged to one of the discharge channels.

FIG. 1 shows a first embodiment of a discharge pipe.

The pipe comprises an inlet 1 designed to be connected to the outlet of a reactor in order to receive the residues of two reactive gases, or of two different mixtures of reactive gases, originating from the reactor, two discharge channels 3 and 5 each connected to a vacuum pump 7 and 9 and a central trunk 11 connecting the inlet 1 of the pipe to the two discharge channels 3 and 5. The discharge channels being made so as to obtain a conductance, for example by having similar dimensions and a similar pumping capacity having the same order of magnitude.

Moreover, each discharge channel comprises respectively first and second means 13 and 15 for injecting an inert gas. These injection means 13 and 15 may for example comprise a first valve 17 and a second valve 18 in order to allow or prevent the passage of the inert gas and a first injection nozzle 19 and a second injection nozzle 20 in order to diffuse the inert gas in the chosen direction, in the direction opposite to the direction of pumping (that is to say against the direction of propagation of the reactive gas in the discharge channel).

Thus, the injection of inert gas 21 in the opposite direction in one of the discharge channels makes it possible to direct the reactive gas towards the other discharge channel as shown in FIG. 2. When the second gas G2 is received at the inlet 1 of the pipe, the first means 13 for injecting inert gas 21 of the first discharge channel 3 are activated (by the opening of the first valve 17) in order to force the residues of reactive gas G2 to travel towards the second discharge channel 5 in order to be transmitted to the second vacuum pump 9, the latter being dedicated to the pumping of the reactive gas G2. The second means 15 for injecting inert gas 21 of the second discharge channel 5 remain inactivated (second valve 18 closed). The inert gas may for example be nitrogen N₂, argon Ar or helium He.

When the gas G1 is received at the inlet 1 of the pipe, the second means 15 for injecting an inert gas 21 of the second discharge channel 5 are activated, while the means 13 for injecting an inert gas 21 of the first discharge channel 3 are deactivated. The gas G1 is therefore directed towards the first vacuum pump 7 dedicated to the pumping of the gas G1.

In practice, the two gases G1 and G2 are usually injected alternately into the reactor so that the activation of the first and second means 13 and 15 for injecting inert gas also takes place alternately depending on the reactive gas G1 or G2 that is present in the reactor.

Furthermore, the quantity of inert gas 21 injected can be regulated depending on the quantity of reactive gas G1 or G2 to be discharged and on the concentration of reactive gas G1 or G2 desired at the vacuum pump 7 or 9. Advantageously, the quantity of inert gas 21 is the same for the two injection sequences of the alternation so as not to modify the pressure inside the reactor and the pipe. The quantity of inert gas injected is calculated to obtain a concentration of 20% reactive gas G1 or G2 in the gas mixture at the vacuum pump, the gas mixture at the vacuum pump consisting of reactive gas G1, G2 and of injected inert gas 21. It is considered that the concentration at the outlet of the reactor of the reactive gas G1 or G2 is 100%.

If necessary, depending on the pumping system, this concentration of reactive gas G1 or G2 at the vacuum pump can be reduced to 1%.

Moreover, according to one embodiment, the first and second injection means 13 and 15 do not totally prevent the passage of the inert gas 21 when they are inactive, but are placed in a standby mode in which a small quantity of inert gas 21 continues to be injected in order to prevent the formation of deposit on the injection nozzles 19 and 20 of the inert gas, thus protecting the injection nozzles 19 and 20.

Moreover, the valves 23 and 25 are situated at the outlet of the discharge channels 3 and 5 and at the inlet of the vacuum pumps 7 and 9. These valves 23 and 25 are automatic valves which remain permanently open in normal operation and are closed in the event of a failure of the corresponding vacuum pump in order to isolate the faulty vacuum pump from the pipe.

Moreover, only two discharge channels are shown in FIGS. 1 and 2, but a pipe comprising a larger number of discharge channels (in order to discharge a larger number of reactive gases) may also be produced. In such a case the means for injecting an inert gas of the various discharge channels, except for the channel connected to the vacuum pump dedicated to the reactive gas in question, will be activated, thus forcing the reactive gas to be directed towards the dedicated vacuum pump.

FIG. 3 shows a second embodiment of the present invention in the case in which the number of discharge channels is equal to two. In this second embodiment, the difference from the pipe explained above relates to the configuration of the central trunk 27. This configuration corresponds to a first tube, connected to the second discharge channel 5 of which the section is smaller than the section of the inlet 1 of the pipe and forming the internal portion 29 of the central trunk 27 and a second tube, connected to the first discharge channel 3 of which the section corresponds to the section of the inlet 1 of the pipe and forming the peripheral portion 31 of the central trunk 27. The sections of the internal portion 29 and of the peripheral portion are calculated so as to obtain conductances of the same order of magnitude between the inlet 1 of the pipe and the respective discharge channels 3 and 5.

FIG. 4 shows a view in cross section of the pipe at its inlet 1 in which the internal portion 29 and peripheral portion 31 of the central trunk 27 have a circular section.

Nevertheless, the present invention may also apply to sections of different shape such as for example oval sections, or even rectangular or square sections.

As for the previous embodiment, the first and second means 33 and 35 for injecting inert gas are used in order to direct the residues of reactive gases G1 or G2 originating from the reactor to one or other of the discharge channels in order to be transmitted to the dedicated vacuum pump 7 or 9.

The first means 33 for injecting inert gas of the peripheral portion 31 are evenly distributed over the perimeter of the peripheral portion 31 (for example by using a set of injection nozzles 32 connected to an inlet of inert gas controlled by a valve 24) at the inlet 1 of the pipe. The means 33 for injecting inert gas are directed towards the centre of the inlet 1 of the pipe so as to create an annular, slightly conical, jet as shown in FIGS. 6 and 7. FIG. 7 shows the direction of the injection of the inert gas at the inlet 1 shown in FIG. 4.

Thus, when the second reactive gas G2 sent to the vacuum pump 9 connected to the second discharge channel 5 connected to the internal portion 29 of the central trunk 27 is received at the inlet 1 of the pipe, the means 33 for injecting inert gas of the peripheral portion 31 are activated (the means 35 for injecting inert gas of the internal portion 29 remaining inactivated) so as to direct the second reactive gas G2 towards the internal portion 29 of the central trunk 27 and consequently towards the corresponding vacuum pump 9.

The second means 35 for injecting inert gas of the internal portion 29 of the central trunk 27 are situated in the axis of the internal portion 29 and at the end opposite to the inlet 1 of the channel and are directed towards the inlet 1 as shown in FIG. 5.

Thus, when the first reactive gas G1 sent to the vacuum pump 7 connected to the first discharge channel 3 connected to the peripheral portion 31 of the central trunk 27 is received at the inlet 1 of the pipe, these means 35 for injecting inert gas are activated by the opening of a valve 22 (the means 33 for injecting inert gas of the peripheral portion 31 remaining inactivated by the closure of the valve 24) so as to prevent the reactive gas G1 from entering the internal portion 29 and to force it to go into the discharge channel 3 connected to the peripheral portion 31 of the central trunk 27.

The use of an injected inert gas 21 therefore constitutes a gas screen making it possible to prevent a reactive gas from entering the selected discharge channel, and consequently to direct a reactive gas into the discharge channel that is dedicated thereto without needing valves or other mechanical elements, the latter being subject to worn by interaction with the reactive gases. The embodiments of the present invention therefore make it possible to avoid the use of mechanical parts that can become immobilized or be blocked, thus improving the lifetime of the pipe while reducing its maintenance. Moreover, the change of direction of the reactive gas from one discharge channel to another can be carried out more rapidly than the solutions of the prior art. Finally, the embodiments of the present invention allow a constant dilution of the reactive gas upstream of the pumping system, thus making its treatment easier.

1. Gas discharge pipe comprising a first discharge channel (3) and at least one second discharge channel (5) designed to be connected respectively to a first vacuum pump (7) and to at least a second vacuum pump (9) on the one hand and to a reactor outlet on the other hand, in which the first discharge channel (3) and at least the second discharge channel (5) comprise first means (13; 33) and at least second means (15; 35) for injecting an inert gas (21) in which the direction of injection is respectively oriented opposite to the direction of suction of the vacuum pumps (7, 9).

2. Gas discharge pipe according to claim 1, comprising a central trunk (11; 27) placing in communication on the one hand the outlet of the reactor and on the other hand the first discharge channel (3) and at least the second discharge channel (5), the first discharge channel (3) and at least the second discharge channel (5) having conductances of the same order of magnitude.

3. Gas discharge pipe according to claim 2, in which the discharge channels (3, 5) are two in number and in which the central trunk (27) comprises on the one hand an internal portion (29) in communication with the second discharge channel (5) and on the other hand a peripheral portion (31) separated from the internal portion (29) by a wall and being in communication with the first discharge channel (3).

4. Gas discharge pipe according to claim 3, in which the respective conductances of the internal portion (29) and of the peripheral portion (31) of the central trunk (27) are of the same order of magnitude.

5. Gas discharge pipe according to claim 4, in which the first injection means (33) for injecting an inert gas (21) are situated in the axis of the internal portion (29) of the central trunk (27) and are oriented towards the outlet of the reactor while the second injection means (35) for injecting an inert gas (21) are situated on the perimeter of the peripheral portion (31) of the central trunk (27), and are oriented substantially towards the centre of the section of the central trunk (27).

6. Method for discharging a first reactive gas (G1) and at least one second reactive gas (G2) originating from a reactor through a discharge pipe according to claim 1, the first reactive gas (G1) and at least the second reactive gas (G2) being discharged sequentially through a first discharge channel (3) and at least one second discharge channel (5) connected respectively to a first vacuum pump (7) and at least one second vacuum pump (9), in which the directing of the flow of a reactive gas (G1, G2) towards one of the discharge channels (3, 5) is controlled by the injection of an inert gas (21) substantially in the direction opposite to the direction of suction of the respective vacuum pumps (7, 9).

7. Discharge method according to claim 6, in which the injection of an inert gas (21) is carried out at the inlet of at least one of the first (3) and at least second (5) discharge channels.

8. Discharge method according to claim 6, in which the first reactive gas (G1) and at least second reactive gas (G2) originating from the reactor are received sequentially, and in which the first vacuum pump (7) and at least second vacuum pump (9) are dedicated respectively to the first reactive gas (G1) and at least to the second reactive gas (G2) so that an inert gas (21) is injected at the first discharge channel (3) when the reactive gas (G2) to be discharged is sent to the second vacuum pump (9) and an inert gas (21) is injected at the second discharge channel (5) when the reactive gas (G1) to be discharged is sent to the first vacuum pump (7).

9. Discharge method according to claim 8, in which the first reactive gas (G1) and at least the second reactive gas (G2) originating from the reactor are received alternately in the pipe, so that the injection of an inert gas (21) at the discharge channels (3, 5) is also carried out alternately.

10. Discharge method according to claim 9, in which the quantity of inert gas (21) that is injected is the same for the two sequences of the alternation and is calculated to obtain a concentration of 20% reactive gas (G1, G2) in the gas mix at the vacuum pump, the gas mix at the vacuum pump consisting of reactive gas (G1, G2) and injected inert gas (21).
